(19) United States
(12) Patent Application Publication
(10) Pub. No.: US 2011/0272801 A1
(43) Pub. Date: Nov. 10, 2011

(54) SEMICONDUCTOR DEVICE WITH CONNECTION PADS PROVIDED WITH INSERTS

(75) Inventors: Vincent Fiori, Grenoble (FR); Philippe Delpech, Meylan (FR); Eric Sabouret, Saint-Ismier (FR)

(73) Assignees: STMICROELECTRONICS S.A., Montrouge (FR); STMICROELECTRONICS (CROLLES 2) SAS, Crolles Cedex (FR)

(21) Appl. No.: 13/100,860

(22) Filed: May 4, 2011

(30) Foreign Application Priority Data
May 6, 2010 (FR) 10 53552

(51) Int. Cl. H01L 23/50

(52) U.S. Cl. 257/737; 257/E23.079

(57) ABSTRACT

A semiconductor device includes an integrated circuit and external electrical connection pads. Each pad includes cavities that are at least partially filled with a material different from the material forming the pads, so as to form inserts.

### PRIORITY CLAIM

This application claims priority from French Application for Patent No. 10-53552 filed May 6, 2010, the disclosure of which is hereby incorporated by reference.

### TECHNICAL FIELD

The present invention relates to the semiconductor devices, and more particularly to external electrical connection pads of semiconductor devices.

### SUMMARY

Currently, semiconductor devices or integrated circuit chips have electrical connection pads for external electrical connection of these integrated circuits via the pads.

During placement of electrical connection means onto the pads of semiconductor devices, for example electrical connection wires or the electrical connection pads of another component, thermomechanical stresses may appear that are liable to damage the parts of the devices located below or near their pads.

To alleviate this, a semiconductor device is provided, which comprises an integrated circuit and external electrical connection pads. The electrical connection pads have cavities at least partially filled with a material that is different from that forming the pads, so as to form inserts.

The cavities may extend over a depth corresponding to a part of the thickness of the pads.

The cavities may extend over the thickness of the pads.

The central part of the pads may be free of any cavity.

The cavities may be symmetrical with respect to the lines joining the midpoints of the sides and to imaginary diagonals of the pads.

The cavities may comprise slot portions.

The slots may be arranged parallel to the sides of the pads.

The pads may be made of aluminum or copper and the material filling the cavities may be made of silicon oxide.

The expansion coefficient and/or the Young's modulus of the filling material may be lower than those of the material forming the pads.

The product of the expansion coefficient and the Young's modulus of the filling material may be smaller than that of the material forming the pads.

### BRIEF DESCRIPTION OF THE DRAWINGS

A semiconductor device comprising electrical connection pads provided with inserts will now be described by way of non-limiting examples and illustrated by the drawings, in which:

FIG. 1 shows a schematic of a side view of a semiconductor device;

FIG. 2 shows a partial cross section of an electrical connection pad provided with an insert according to a first embodiment;

FIG. 3 shows a partial cross section of an electrical connection pad provided with an insert according to another embodiment;

FIG. 4 shows a top view of an electrical connection pad provided with an insert;

FIG. 5 shows a top view of an electrical connection pad provided with another insert;

FIG. 6 shows a top view of an electrical connection pad provided with another insert;

FIG. 7 shows a top view of an electrical connection pad provided with another insert;

FIG. 8 shows a top view of an electrical connection pad provided with another insert;

FIG. 9 shows a top view of an electrical connection pad provided with another insert; and

FIG. 10 shows a top view of an electrical connection pad provided with another insert.

### DETAILED DESCRIPTION OF THE DRAWINGS

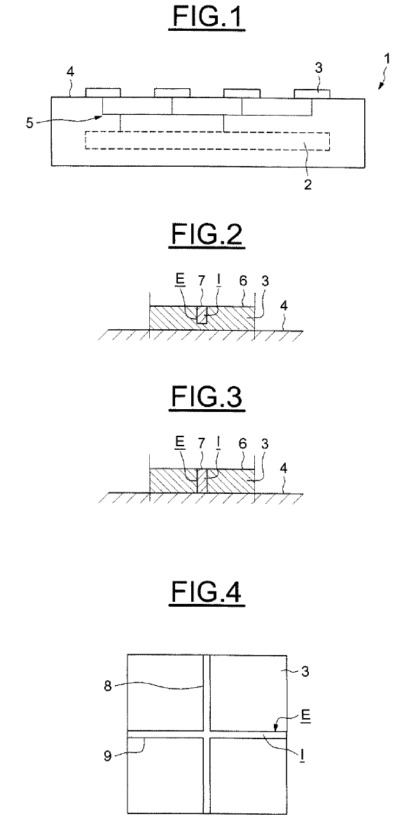

As illustrated in FIG. 1, a semiconductor device or chip 1, generally parallelepiped-shaped and with a square outline, comprises an electronic integrated circuit 2, external electrical connection pads 3, made of a material that conducts electricity, arranged on a front side 4, and a integrated electrical connection network 5 allowing the electronic integrated circuit 2 to be selectively linked to the external electrical connection pads 3. In the example described, the external electrical connection pads 3 are parallelepiped-shaped and have a square outline.

The front sides 6 of the pads 3 are intended to receive electrical connection means such as the ends of electrical connection wires, electrical connection columns or electrical connection pads or another electronic component.

It is proposed to arrange in the pads 3, in their thickness direction, cavities E and to fill, at least partially, these cavities E with a different material from that forming these pads 3 so as to form inserts I.

According to the embodiment illustrated in FIG. 2, the cavities E may extend from the front side of the pads 3 over a part of the thickness of the pads 3.

According to the embodiment illustrated in FIG. 3, the cavities E may extend from the front side 6 of the pads 3 over the entire thickness of the pads 3 such that the inserts I make contact with the front side 4 of the semiconductor devices 1.

The inserts I may have an external side 7 located level with the front side 6 of the pads 3.

The arrangement of the cavities E may be such that the cavities E, and consequently the inserts I that fill them, have axes of symmetry along imaginary lines joining the midpoints of the sides of the pads 3 and axes of symmetry along imaginary diagonals of the pads 3.

Various arrangements of the cavities E will now be described.

According to one embodiment illustrated in FIG. 4, the cavities E take the form of two crossed slots 8 and 9, arranged along the lines joining the midpoints of the sides of the pads 3, and that extend from one side of the pads 3 to the other, such that the slots 8 and 9, and consequently the inserts I that fill them are symmetrical with respect to imaginary lines joining the midpoints of the sides of the pads 3 and relative to imaginary diagonals of the pads 3. The inserts I may appear in form as beams extending across the pads 3.

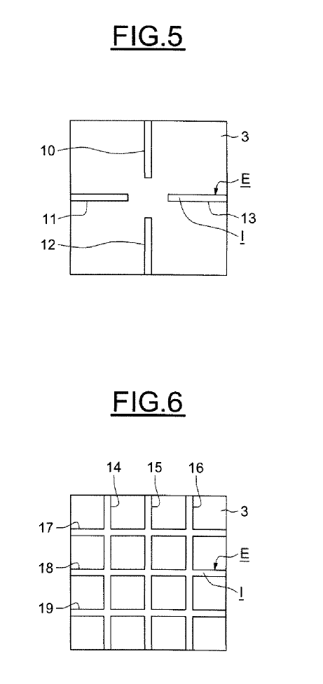

According to the embodiment illustrated in FIG. 5, the cavities E take the form of four crossed slot portions 10, 11, 12 and 13, arranged along the lines joining the midpoints of the sides of the pads 3, and that extend from each side of the pads 3, without joining one another in the central part of the pads 3, such that the central part of the pads 3 is free of any cavity. The slots 10, 11, 12 and 13, and consequently the inserts I that fill them, define a symmetrical arrangement with respect to imaginary lines joining the midpoints of the sides of the pads 3 and with respect to imaginary diagonals of the pads 3.

According to the embodiment illustrated in FIG. 6, the cavities E take the form of three slots 14, 15 and 16 parallel to two opposite sides of the pads 3 and three slots 17, 18 and 19 parallel to two other opposite sides of the pads 3 and run, respectively, from one side of the pads 3 to the other, such that these slots, and consequently the inserts I that fill them, define a grid. Thus, this arrangement of cavities E is such that the cavities E formed by this grid, and consequently the inserts I that fill them, have axes of symmetry along imaginary lines joining the midpoints of the sides of the pads 3 and axes of symmetry along imaginary diagonals of the pads 3.

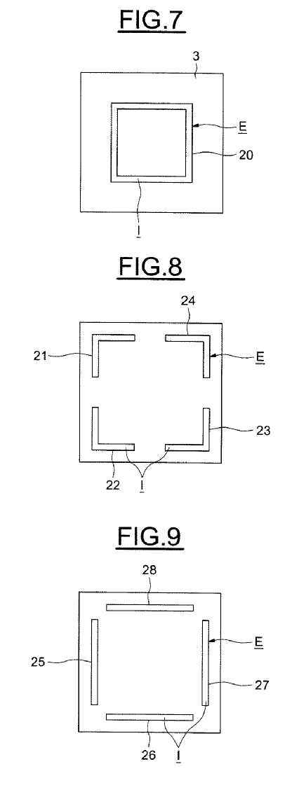

According to the embodiment illustrated in FIG. 7, the cavities E, which define the inserts I, take the form of a continuous slot 20 forming a square. The sides of the square are parallel to and located at equal distance from the sides of the pads 3.

According to the embodiment illustrated in FIG. 8, the cavities E comprise four slots 21, 22, 23 and 24 that extend in the form of L's placed in the corners of the pads 3, the arms of which are of equal length and lie parallel to and at equal distances from the respective sides of the pads 3. Thus, this arrangement of cavities E, and consequently the inserts I that fill them, is also such that it is symmetrical about imaginary lines joining the midpoints of the sides of the pads 3 and about imaginary diagonals of the pads 3.

According to the embodiment illustrated in FIG. 9, the cavities E comprise four straight slots 25, 26, 27 and 28, of the same length, parallel to and at equal distances from the respective sides of the pads 3. These four slots 25, 26, 27 and 28 are placed such that they are symmetrical about the lines joining imaginary midpoints of the sides of the pads 3 and about imaginary diagonals of the pads 3.

In the case of the variants in FIGS. 7, 8 and 9, the corresponding cavities E are placed closer to the sides of the pads 3 than to their centers.

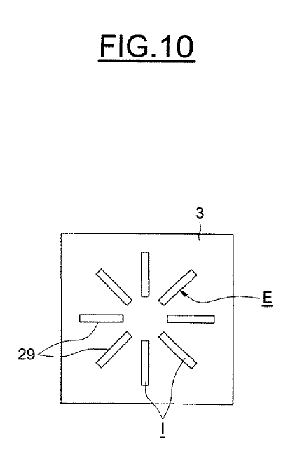

According to the embodiment illustrated in FIG. 10, the cavities E, defining inserts I, comprise eight slots of the same length located radially about a central part of the pads 3 and uniformly distributed.

The expansion coefficient and Young's modulus of the filling material are lower than those of the material forming the pads 3. In addition, the product of the expansion coefficient and the Young's modulus of the filling material may be smaller than that of the material forming the pads 3.

The material forming the inserts I may be such that its expansion coefficient and its Young's modulus are lower than those of the material forming the pads 3.

For example, in the case where the pads 3 are made of aluminum or copper, the inserts I may be made of silicon oxide.

By way of an exemplary embodiment, if the sides of the pads 3 are between 50 and 100 microns long, the slots forming the cavities E may be between 3 and 10 microns wide and may be between 40 and 90 microns long.

If the cavities E are not established through the entire thickness of the pads 3, their depth may be at least equal to 80 percent of the thickness of the pads 3.

For example, after having produced cavities E by etching, it is possible to produce the inserts I by deposition, using means conventionally employed in microelectronics.

By virtue of the arrangement of the inserts I in the pads 3, stresses are accommodated. That is to say, the mechanical strength of the device 1 is improved, especially near the pads 3, via a reduction in the mechanical effects of the forces applied during the placement of the aforementioned external electrical connection means onto the pads 3.

The present invention is not limited to the examples described above. The arrangements, shapes and dimensions of the cavities E defining the inserts I could be different. In addition, the pads 3 could have rectangular, circular or polygonal outlines. Moreover, the arrangements, shapes and dimensions of the cavities E defining the inserts I may be matched to such outlines.

Other variants are possible without departing from the scope defined by the appended claims.

What is claimed is:

1. A semiconductor device, comprising:
an integrated circuit; and
at least one external electrical connection pad having a plurality of cavities, the plurality of cavities being at least partially filled with a material different from that forming the pad, so as to form a plurality of inserts.

2. The device of claim 1, wherein the plurality of cavities extend over a depth corresponding to a part of a thickness of the pad.

3. The device of claim 1, wherein the plurality of cavities extend over a depth corresponding to a thickness of the pad.

4. The device of claim 1, wherein a central part of the pad is free of any cavity.

5. The device of claim 1, wherein the plurality of cavities are symmetrical with respect to imaginary lines between the midpoints of the sides and imaginary diagonals of the pad.

6. The device of claim 1, wherein the plurality of cavities comprise slots, each slot having a length greater than its width.

7. The device of claim 6, wherein the slots are each arranged parallel to a respective side of the pad.

8. The device of claim 1, wherein the pad is made of aluminum or copper and the material filling the cavities includes silicon oxide.

9. The device of claim 1, wherein an expansion coefficient and a Young's modulus of the filling material are each lower than those of the material forming the pad.

10. The device of claim 9, wherein a product of the expansion coefficient and the Young's modulus of the filling material is less than that of the material forming the pad.

11. A semiconductor device, comprising:
an integrated circuit;
a connection pad electrically coupled to the integrated circuit and having a face defining a cavity;
an insert formed in the cavity, wherein the insert is formed of an insert material that is different than a pad material forming the connection pad.

12. The device of claim 11, wherein the cavity is continuous and includes a plurality of linear portions, each linear portion being parallel to an edge of the face.

13. The device of claim 11, wherein:
the cavity is one of a plurality of cavities, each cavity having a respective insert formed of the insert material; and
the plurality of cavities form a pattern having lines of symmetry comprising:
a first midpoint line bisecting a first pair of opposite edges of the face;
a second midpoint line bisecting a second pair of opposite edges of the face;
a first diagonal line between a first pair of opposite corners of the face; and
a second diagonal line between a second pair of opposite corners of the face.

14. The device of claim 11, wherein the cavity is one of a plurality of cavities, each cavity having a respective insert formed of the insert material, the plurality of cavities being uniformly and radially distributed about a center of the face.

15. The device of claim 11, wherein the cavity extends to a depth that is less than a thickness of the pad.

16. The device of claim 11, wherein the cavity extends to a depth that corresponds to a thickness of the pad.

17. The device of claim 11, wherein the cavity extends to intersect a midpoint of a first edge of the face; and further comprising a second cavity extending to intersect a midpoint of a second edge of the face that is perpendicular to the first edge, the second cavity having a second insert formed of the insert material.

18. The device of claim 17, wherein the cavity intersects with the second cavity at a center of the face.

19. The device of claim 11, wherein the insert material has a Young's modulus that is less than a Young's modulus of the pad material.

20. The device of claim 19, wherein insert material is silicon oxide.

21. A semiconductor device, comprising:
an integrated circuit;
a plurality of connection pads, each connection pad being electrically coupled to the integrated circuit, each connection pad having a plurality of cavities forming a pattern on a respective face of a respective connection pad;
an insert formed in each respective cavity, the insert being formed of an insert material that is different from a pad material forming the connection pad; and
wherein the insert material has a Young's modulus that is less than a Young's modulus of the pad material.

22. The semiconductor device of claim 21, wherein the pattern is uniformly and radially distributed about a center of the face.

23. The semiconductor device of claim 21, wherein:
each one of the plurality of cavities is parallel to an edge of the face;
a first cavity extends to intersect a midpoint of a first edge of the face; and
a second cavity extends to intersect a midpoint of a second edge of the face that is perpendicular to the first edge.
